(19) United States
(12) Patent Application Publication
(10) Pub. No.: US 2026/0293759 A1
(43) Pub. Date: Sep. 24, 2026

(54) INTEGRATED CIRCUIT WITH EMBEDDED SUBSTRATE AND MAGNETIC MOLD COMPOUND

(71) Applicant: TEXAS INSTRUMENTS INCORPORATED, Dallas, TX (US)

(72) Inventors: Yunyi GONG, Shinagawa (JP); Hidetoshi INOUE, Oyama (JP); Kenji OTAKE, Karuizawa (JP)

(21) Appl. No.: 19/086,565

(22) Filed: Mar. 21, 2025

(51) Int. Cl. H01L 25/16; H01L 21/56; H01L 23/00; H01L 23/13; H01L 23/29; H01L 23/495; H01L 23/498; H01L 23/538; H01L 23/64; H05K 1/18; H10D 80/20

(52) U.S. Cl. CPC H10W 90/00; H05K 1/181; H10D 80/211; H10W 44/501; H10W 70/611; H10W 70/65; H10W 70/68; H10W 70/69; H10W 74/016; H10W 74/40; H10W 90/701; H10W 70/429; H10W 90/794

(57) ABSTRACT

A packaged integrated circuit includes: a semiconductor die; an inductor on the semiconductor die; a dielectric laminate structure including multiple dielectric layers; a metal interconnect structure in the dielectric laminate structure and coupled between the inductor and the semiconductor die; and a magnetic mold compound covering the inductor. The magnetic mold compound has at least a same footprint as the dielectric laminate structure.

### BACKGROUND

An inductor can store energy in a magnetic field when electric current flows through the inductor and can provide an electric current by discharging the stored energy. Inductors can have many applications, such as proximity sensing, energy storage, actuation, power transmission, and filtering. A packaged integrated circuit (IC) may include an external inductor coupled to an IC, which can include circuits that operate with the inductor to support those and other applications. The packaged IC may include magnetic mold compound. Two issues that negatively affect packaged ICs with an external inductor and magnetic mold compound are: inductance inefficiency (lower power density) due to low permeability of the magnetic mold compound material; and parasitic impedance/breakdown risk due to the magnetic mold compound material being non-insulating and magnetic.

### SUMMARY

In an example, a packaged integrated circuit includes: a semiconductor die; an inductor on the semiconductor die; a dielectric laminate structure including multiple dielectric layers; a metal interconnect structure in the dielectric laminate structure and coupled between the inductor and the semiconductor die; and a magnetic mold compound covering the inductor. The magnetic mold compound has at least a same footprint as the dielectric laminate structure.

In another example, system includes: a circuit board; a power module mounted on the circuit board. The power module includes: a semiconductor die; an inductor on the semiconductor die; a dielectric laminate structure including multiple dielectric layers; a metal interconnect structure in the dielectric laminate structure and coupled between the inductor and the semiconductor die; and a magnetic mold compound covering the inductor, the magnetic mold compound having at least a same footprint as the packaged integrated circuit; and a processor mounted on the circuit board.

In another example, a method includes: mounting an inductor on a dielectric laminate structure having multiple dielectric layers and a metal interconnect structure, the metal interconnect structure coupled to a semiconductor die and the inductor; covering the inductor coupled to the dielectric laminate structure with a magnetic mold compound; and dicing at least one of the magnetic mold compound or the dielectric laminate structure so that the magnetic mold compound has a same footprint as the dielectric laminate structure.

### BRIEF DESCRIPTION OF THE DRAWINGS

FIG. 1 is a block diagram of a packaged integrated circuit (IC) with an inductor and a magnetic mold compound, in an example.

FIGS. 2, 3, 4, 5, 6, and 7 are perspective views of packaged ICs, in different examples.

FIGS. 8 and 9 are perspective views of inductors in a magnetic mold compound, in different examples.

FIGS. 10A, 10B, and 10C are different views of a core for an inductor, in an example.

FIG. 11 is a cross-sectional view of a system, in an example.

FIG. 12 is a flowchart illustrating a method for fabricating a packaged IC, in an example.

FIGS. 13A, 13B, 13C, 13D, and 13E are cross-sectional views of a device during the fabrication of a packaged IC, in an example.

### DETAILED DESCRIPTION

The same reference numbers or other reference designators are used in the drawings to designate the same or similar (either by function and/or structure) features.

In some examples, a packaged integrated circuit (IC) has an inductor and magnetic mold compound (MMC) covering the inductor. MMC may include a polymer bonded magnetic material and may include magnetic/metallic particles suspended in a thermosetting insulator. Examples of MMC may include, for example, iron (Fe)-based metal filler, nano-Crystalline, ferrite, neodymium, samarium-cobalt, or other magnetic/metallic particles in a polymer, which can include epoxy resin, Acrylic resin, hardener (e.g., phenol resin), Bismaleimide, and may include additives such as curing accelerator/elastomer/coupling agent/wax. In some examples, the magnetic/metallic particles can be coated with an insulator, such as SiO₂, as described in U.S. application Ser. No. 17/852,979, Attorney Docket Number T101732US01, filed on Jun. 29, 2022, which is incorporated by reference.

In such examples, the IC includes a semiconductor die embedded in an encapsulation material, which can include dielectric layers and/or mold compound. The embedded semiconductor die is coupled to the inductor via a metal interconnect structure that is embedded in another dielectric laminate structure including multiple dielectric layers. In some examples, the semiconductor die and the metal interconnect structure are embedded in a same dielectric laminate structure. The IC also include external interconnects to provide electrical connections between the semiconductor die and/or the inductor and an external system. Different examples of the packaged IC are possible with variations based on: different orientations of the embedded semiconductor die; the number of embedded semiconductor dies; the use of embedded passive components; different lead frame positions; different external interconnects; the use of external passive components; use of an inductor core; different dielectric laminate structures to support different packaged IC options; and different metal interconnect structures to support different packaged IC options. Examples of the packaged IC described herein improve inductance efficiency and reduce parasitic impedance/breakdown issues due to magnetic mold compound properties. In some examples, the packaged IC is a power module with power converter circuitry, where use of an external inductor, inductor core, embedded semiconductor die, dielectric laminate structure, and metal interconnect structure improves the power density of the power module and reduces leakage currents between external and embedded components.

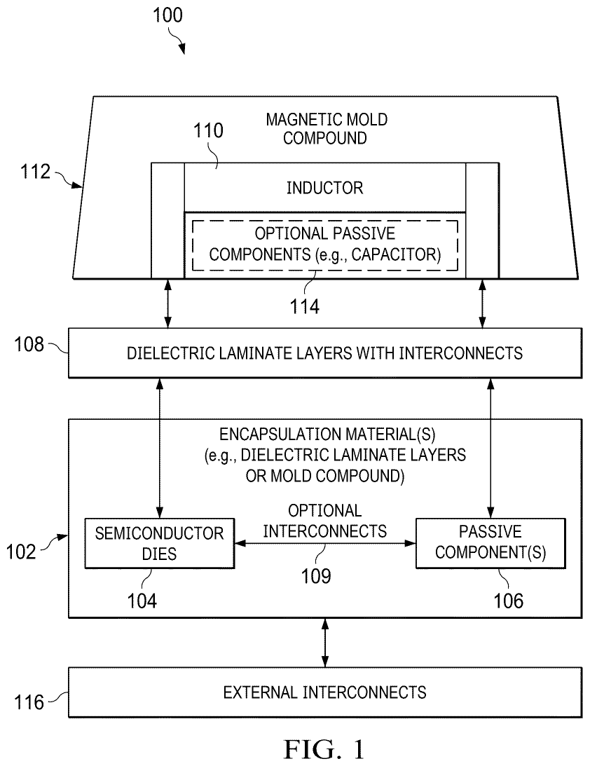

FIG. 1 is a block diagram of a packaged IC 100 with an inductor 110 and magnetic mold compound 112 covering and/or surrounding inductor 110. In the example of FIG. 1, the packaged IC 100 also includes dielectric layers 108, encapsulation material(s) 102, and external metal interconnects 116 (e.g., leads, pads, bumps, etc. to provide electrical connection between components of packaged IC 100 (e.g., inductor 110 and semiconductor die(s) 104) and another system external to packaged IC 100) forming a stack. In the example of FIG. 1, the dielectric layers 108 can form a dielectric laminate structure surrounding/encapsulating an internal metal interconnect structure that provide electrical connections between inductor 110 and semiconductor die(s) 104 within packaged IC 100. In some examples, the dielectric layers 108 may include layers of Bismaleimide Triazine (BT), Ajinomoto Build-up Film (ABF), polyimide, epoxy, or other types of organic or inorganic dielectric layers to provide electrical insulation between the metal interconnects of the internal metal interconnect structure. Dielectric layers 108 can also provide reduced magnetic permeability to block (or at least attenuate) the magnetic field of inductor 110 from reaching and magnetizing a package substrate (e.g., a lead frame) coupled to external interconnects 116 and reducing loop inductance as well as switching loss caused by the loop inductance, in examples where packaged IC 100 includes a switch mode power converter.

The encapsulation material(s) 102 may include dielectric layers, which can be the same as those of dielectric layers 108, and/or mold compound. As shown, the encapsulation material(s) 102 may surround/encapsulate semiconductor die(s) 104 mounted on a package substrate. In some examples, the encapsulation material(s) 102 also surround/encapsulate passive component(s) 106. In such examples, the encapsulation material(s) 102 may include optional interconnects 109 between the semiconductor die(s) 104 and the passive component(s). Examples of the passive component(s) 106 include resistors, capacitors, and inductors. Encapsulation material(s) 102 (in addition to dielectric layers 108) can further block (or at least attenuate) the magnetic field of inductor 110 from reaching and magnetizing external interconnects 116 and reducing loop inductance as well as switching loss caused by the loop inductance.

In some examples, the packaged IC 100 includes optional passive component(s) 114 (sometimes referred to as an external passive component herein due to the passive component(s) 114 being separate from the semiconductor die(s) 104 and the encapsulation material(s) 102). Example passive components include capacitors and/or resistors). The passive components 114 may be mounted, for example, in space between the inductor 110 and the dielectric layers 108. If passive components 114 are used, the dielectric layers 108 may include interconnects to couple each of the passive components 114 to a respective component of the encapsulation material(s) 102 and/or to respective interconnects of the external interconnects 116.

In some examples, the packaged IC includes: a semiconductor die (e.g., one of the semiconductor die(s) 104); an inductor (e.g., the inductor 110) on the semiconductor die; a dielectric laminate structure (e.g., the dielectric layers 108) including multiple dielectric layers; a metal interconnect structure (e.g., interconnects surrounded by the dielectric layers 108) in the dielectric laminate structure and coupled between the inductor and the semiconductor die; and a magnetic mold compound (e.g., the magnetic mold compound 112) covering the inductor.

In some examples, the magnetic mold compound has at least a same footprint (e.g., an area on a plane orthogonal to an axis along with magnetic mold compound 112, dielectric layers 108, and encapsulation material(s) 102 are stacked) as the dielectric layers 108 and encapsulation material(s) 102. Such arrangements can improve the power density of packaged IC. Specifically, the magnetic mold compound can concentrate the magnetic field of the inductor, so that the effective inductance can be increased with an inductor with reduced number of coils and/or reduced footprint, which in turn can shrink the overall footprint and size of the packaged IC including the inductor. The effective inductance and the magnetic energy in the magnetic mold compound can be related to each other based on the following equation:

$$L = \frac{2 W}{{I}^{2}} \qquad ( Equation 1 )$$

In Equation 1, I is the current, W is the total energy in the magnetic mold compound, and L is the inductance. Assuming a same coil winding of inductor 110 and a same current in it, with more magnetic mold compound around the inductor, more energy can be stored in the magnetic mold compound, and the effective inductance L can increase, which in turn allows a higher power density in the packaged IC. To simplify fabrication and to improve the structural strength the magnetic mold compound, the magnetic mold compound may have the same footprint as (and is entirely on) the dielectric layers 108 and encapsulation material(s) 102, and may define the overall footprint of the packaged IC.

In some examples, at least part of the dielectric laminate structure (e.g., the dielectric layers 108) is between the inductor (e.g., the inductor 110) and the semiconductor die (e.g., the semiconductor die(s) 104). In some examples, the semiconductor die (e.g., the semiconductor die(s) 104) is between the inductor (e.g., the inductor 110) and at least part of the dielectric laminate structure (e.g., dielectric layers 108)

In some examples, a packaged IC (e.g., the packaged IC 100 in FIG. 1) includes: a package substrate on which the semiconductor die is mounted and covered by encapsulation material(s) 102; and external metal interconnects (e.g., the external interconnects 116) coupled to the package substrate. In some examples, the external metal interconnects include at least one of: metal pads, solder balls, or leads. In some examples, the package substrate and the external metal interconnects are part of a ball grid array (BGA) package, a land grid array (LGA) package, or a quad flat no-lead (QFN) package. In some examples, the package substrate is between the inductor and the semiconductor die. In some examples, the package substrate includes a recess, and the semiconductor die is in the recess. In some examples, the semiconductor die is a first semiconductor die, and the packaged IC includes a second semiconductor die coupled to the metal interconnect structure.

In some examples, the dielectric laminate structure (e.g., the dielectric layers 108) is a first dielectric laminate structure, the metal interconnect structure (e.g., the interconnects of the dielectric layers 108) is a first metal interconnect structure, the packaged IC further includes a second dielectric laminate structure (e.g., part of the encapsulation material(s) 102) and a second metal interconnect structure (e.g., interconnects 109 or other interconnects of the encapsulation material(s) 102) in the second dielectric laminate structure, and the semiconductor die is between the first and second dielectric laminate structures.

In some examples, the inductor (e.g., the inductor 110) includes a coil, the packaged IC includes a core that includes at least a portion that extends though the coil, and the magnetic mold compound covers the inductor and the core. In some examples, the portion is a first portion, and the core includes a second portion between the coil and the semiconductor die. In some examples, the first and second portions of the core form a T-shape. In some examples, the packaged IC includes a passive component (e.g., a passive component 114) covered by the magnetic mold compound and coupled to the semiconductor die via the metal interconnect structure.

In some examples, at least one of first dielectric laminate structure and the second dielectric laminate structure include build-up films. In some examples, at least at least one of first dielectric laminate structure and the second dielectric laminate structure include at least one of: epoxy, benzoxazine, polyimide, or bismaleimide-triazine. In some examples, the semiconductor die and the inductor are part of a power converter.

In different examples, the semiconductor die(s) 104 includes a semiconductor die with pads facing the inductor 110 (i.e., a “face-up” semiconductor die). In such examples, one or more interconnects of the dielectric layers 108 may couple the inductor 110 to pads on the face-up side of the face-up semiconductor die. In other examples, the semiconductor die(s) 104 includes a semiconductor die with pads facing away from the inductor 110 (i.e., a “face-down” semiconductor die). In such examples, one or more interconnects of the dielectric layers 108 may couple the inductor 110 to pads on the face-down side of the face-down semiconductor die.

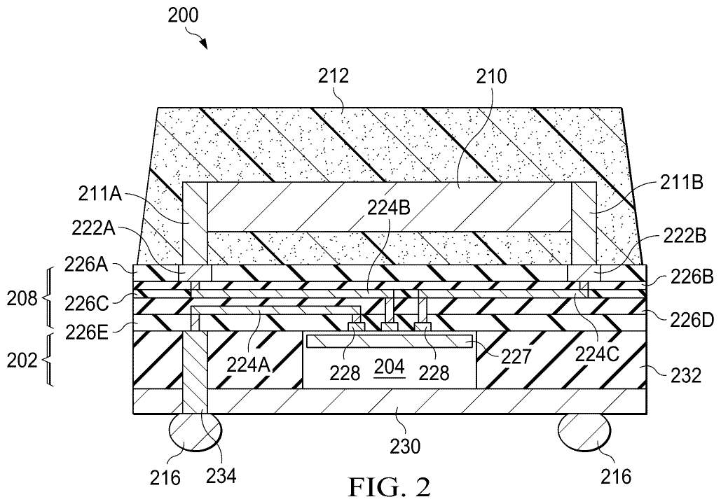

FIGS. 2 to 7 are perspective views of packaged ICs 200, 300, 400, 500, 600, and 700, in different examples. In the example of FIG. 2, the packaged IC 200 includes: an inductor 210 (an example of the inductor 110 in FIG. 1); a magnetic mold compound 212 (an example of the magnetic mold compound 112 in FIG. 1); a semiconductor die 204 (an example of the semiconductor die(s) 104 in FIG. 1); a dielectric laminate structure 208 (an example of the dielectric layers 108 in FIG. 1); an embedded die structure 202; and external interconnects 216 (an example of the external interconnects 116 in FIG. 1). In the example of FIG. 2, the semiconductor die 204 is a face-up semiconductor die (with pads facing the inductor 210). As shown in FIG. 2, the inductor 210 has a first terminal 211A and a second terminal 211B. The first terminal 211A of the inductor 210 is coupled to a first exposed pad 222A. The second terminal 211B of the inductor 210 is coupled to a second exposed pad 222B.

In the example of FIG. 2, the dielectric laminate structure 208 includes a first dielectric layer 226A, a second dielectric layer 226B, a third dielectric layer 226C, a fourth dielectric layer 226D, and a fifth dielectric layer 226E forming a laminate structure. The dielectric laminate structure 208 also surround metal interconnects 224A, 224B, and 224C. In some examples, metal interconnects 224A, 224B, and 224C can include pillars, columns, etc. In some examples, metal interconnects 224A-224C can be part of a redistribution layer. The dielectric laminate structure 208 can provide improved electrical insulation (e.g., compared with magnetic mold compound) between metal interconnects 224A-224C. The dielectric laminate structure 208 and the metal interconnects 224A, 224B, and 224C are between the semiconductor die 204 and the inductor 210 (and the magnetic mold compound 212).

Also, the embedded die structure 202 includes the semiconductor die 204, a via 234, and encapsulation material(s) 232, which can be examples of encapsulation material(s) 102. In some examples, the encapsulation material(s) 232 includes a mold compound. In other examples, the dielectric laminate structure 208 is a first dielectric laminate structure, and the encapsulation material(s) 232 include a second dielectric laminate structure. The semiconductor die 204 includes a metallization structure 227 and pads 228. In other examples, the pads 228 are part of the metal interconnects 224A, 224B, and 224C. In such examples, the pads 228 are coupled to (e.g., soldered) to surface pads of the semiconductor die 204.

Each of the metal interconnects 224A, 224B, and 224C is coupled to a respective pad of the pads 228. More specifically, the metal interconnect 224A couples a respective pad of the pads 228 to the via 234 in the embedded die structure 202. The metal interconnect 224B couples a respective pad of the pads 228 to the first exposed pad 222A and the first terminal 211A of the inductor 210. The metal interconnect 224C couples a respective pad of the pads 228 to the second exposed pad 222B and the second terminal 211B of the inductor 210.

In some examples, the first dielectric layer 226A includes dielectric laminate material, the first exposed pad 222A, and the second exposed pad 222B. The second dielectric layer 226B includes dielectric materials covering first vertical portions of the metal interconnects 224B and 224C. The third dielectric layer 226C includes dielectric materials covering horizontal portions of the metal interconnects 224B and 224C. The fourth dielectric layer 226D includes dielectric materials covering a horizontal portion of the metal interconnect 224A and second vertical portions of the metal interconnects 224B and 224C. The fifth dielectric layer 226E includes dielectric materials covering vertical portions of the metal interconnects 224A, 224B, and 224C. In different examples, the dielectric laminate structure 208 may vary with regard to the number of dielectric layers, the number of interconnects covered by the dielectric layers may also vary, etc.

In the example of FIG. 2, the packaged IC 200 includes a package substrate, such as a lead frame 230 (e.g., a routable lead frame (RLF)), under the semiconductor die 204, such that the semiconductor die 204 is between the lead frame 230 and the magnetic mold compound 212. As shown, the via 234 extends from the fifth dielectric layer 226E to a respective external interconnect of the external interconnects 216 via the lead frame 230. The lead frame 230 may also include other interconnects which couple to respective external interconnects of the external interconnects 216.

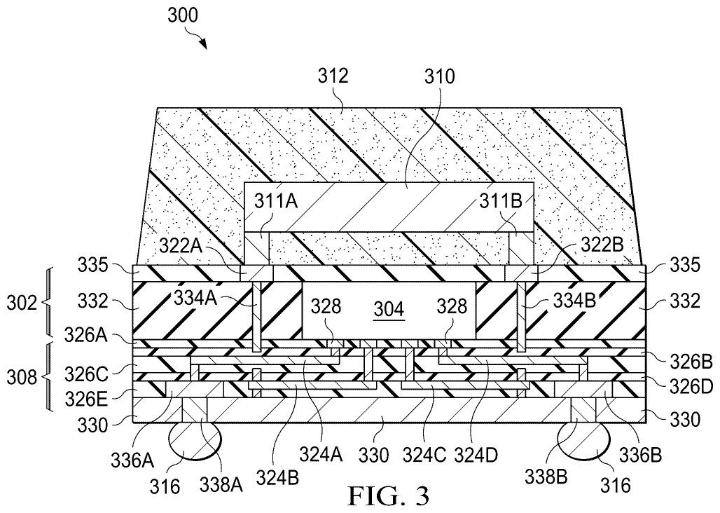

In the example of FIG. 3, the packaged IC 300 includes: an inductor 310 (an example of the inductor 110 in FIG. 1); a magnetic mold compound 312 (an example of the magnetic mold compound 112 in FIG. 1); an embedded die structure 302 including a semiconductor die 304 (an example of the semiconductor die(s) 104 in FIG. 1); a dielectric laminate structure 308 (an example of the dielectric layers 108 in FIG. 1); and external interconnects 316 (an example of the external interconnects 116 in FIG. 1). In the example of FIG. 3, the semiconductor die 304 is a face-down semiconductor die (with pads facing away from the inductor 310). As shown in FIG. 3, the inductor 310 has a first terminal 311A and a second terminal 311B. The first terminal 311A of the inductor 310 is coupled to a first exposed pad 322A. The second terminal 311B of the inductor 310 is coupled to a second exposed pad 322B.

In the example of FIG. 3, the dielectric laminate structure 308 includes a first dielectric layer 326A, a second dielectric layer 326B, a third dielectric layer 326C, a fourth dielectric layer 326D, and a fifth dielectric layer 326E forming a laminate structure. The dielectric laminate structure 308 also includes metal interconnects 324A, 324B, 324C, and 324D. The semiconductor die 304 is between the inductor 310 (and the magnetic mold compound 312) and the dielectric laminate structure 308 (and the metal interconnects 324A, 324B, and 324C).

The embedded die structure 302 includes the semiconductor die 304, vias 334A and 334B, and encapsulation material(s) 332. In some examples, the encapsulation material(s) 332 include a mold compound. In other examples, the dielectric laminate structure 308 is a first dielectric laminate structure, and the encapsulation material(s) 332 include a second dielectric laminate structure. The semiconductor die 304 includes pads 328. In other examples, the pads 328 are part of the metal interconnects 324A, 324B, 324C, and 324D. In such examples, the pads 328 may be coupled to (e.g., soldered) to surface pads of the semiconductor die 304.

In the example of FIG. 3, the packaged IC 300 includes a package substrate (e.g., a lead frame) 330 under the dielectric laminate structure 308, such that the semiconductor die 304 is between the lead frame 330 and the magnetic mold compound 312. The lead frame 330 includes a first pad 336A, a second pad 336B, a first interconnect 338A, and a second interconnect 338B, which can include pillars, columns, and/or can be part of a redistribution layer and can be electrically insulated by the dielectric laminate structure 308. Each of the metal interconnects 324A, 324B, 324C, and 324D is coupled to a respective pad of the pads 328. More specifically, the metal interconnect 324A couples a respective pad of the pads 328 to the first pad 336A and first interconnect 338A of the lead frame 330. The metal interconnect 324B couples a respective pad of the pads 328 to the first exposed pad 322A and the first terminal 311A of the inductor 310. The metal interconnect 324C couples a respective pad of the pads 328 to the second exposed pad 322B and the second terminal 311B of the inductor 310. The metal interconnect 324D couples a respective pad of the pads 328 to the second pad 336B and the second interconnect 338B of the lead frame 330.

In some examples, the first exposed pad 322A and the second exposed pad 322B are surrounded by a dielectric layer 335, which can be part of a dielectric laminate structure of embedded die structure 302. The first dielectric layer 326A of the dielectric laminate structure 308 includes dielectric materials covering portions of the vias 334A and 334B, and the pads 328. The second dielectric layer 326B of the dielectric laminate structure 308 includes dielectric materials covering portions of the vias 334A and 334B and vertical portions of the metal interconnects 324A, 324B, 324C, and 324D. The third dielectric layer 326C includes dielectric laminate materials covering horizontal and vertical portions of the metal interconnects 324A and 324D, vertical portions of the metal interconnects 324B and 324C, and portions of the vias 334A and 334B. The fourth dielectric layer 326D includes dielectric laminate materials covering vertical portions of the metal interconnects 324A, 324B, 324C, 324C, and portions of the vias 334A and 334B. The fifth dielectric layer 326E covers horizontal portions of the metal interconnects 324B and 324C, portions of the vias 334A and 334B, the first pad 336A, and the second pad 336B. In different examples, the dielectric laminate structure 308 may vary with regard to the number of dielectric layers, and the number of interconnects covered by the dielectric layers may vary as well.

In the example of FIG. 3, the first interconnect 338A of the lead frame 330 couples to a respective external interconnect of the external interconnects 316. The second interconnect 338B of the lead frame 330 couples to another respective external interconnect of the external interconnects 316.

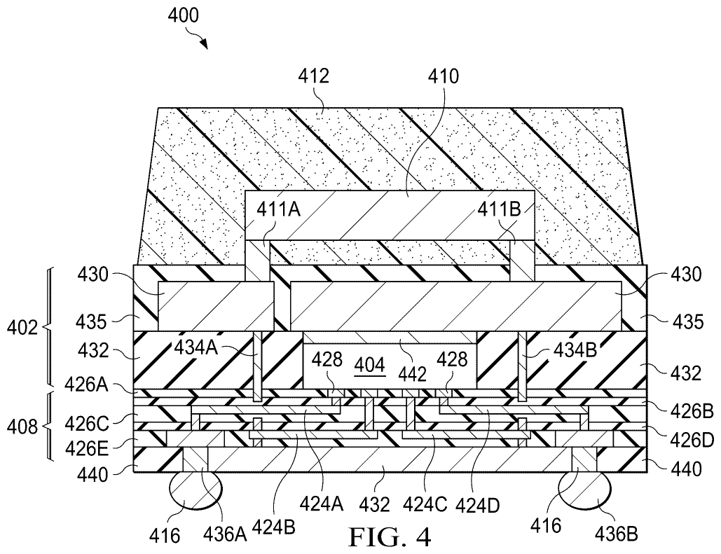

In the example of FIG. 4, the packaged IC 400 includes: an inductor 410 (an example of the inductor 110 in FIG. 1); a magnetic mold compound 412 (an example of the magnetic mold compound 112 in FIG. 1); an embedded die structure 402 including a semiconductor die 404 (an example of the semiconductor die(s) 104 in FIG. 1); a dielectric laminate structure 408 (an example of the dielectric layers 108 in FIG. 1); and external interconnects 416 (an example of the external interconnects 116 in FIG. 1). In the example of FIG. 4, the semiconductor die 404 is a face-down semiconductor die (with pads facing away from the inductor 410). As shown in FIG. 4, the inductor 410 has a first terminal 411A and a second terminal 411B.

In the example of FIG. 4, the dielectric laminate structure 408 includes a first dielectric layer 426A, a second dielectric layer 426B, a third dielectric layer 426C, a fourth dielectric layer 426D, and a fifth dielectric layer 426E. The dielectric laminate structure 408 covers (and provides electrical insulations to) metal interconnects 424A, 424B, 424C, and 424D, which can be pillars, columns, and/or be part of a redistribution layer. The embedded die structure 402 include the semiconductor die 404, vias 434A and 434B, a first encapsulation material(s) 432, a lead frame (package substrate) 430, and a second encapsulation material(s) 435 covering lead frame 430, and an insulation layer 440. In some examples, the first encapsulation material(s) 432 is a mold compound. In other examples, the dielectric laminate structure 408 is a first dielectric laminate structure, and the first encapsulation material(s) 432 is a second dielectric laminate structure. In some examples, the second encapsulation material(s) 435 is a mold compound. In other examples, the second encapsulation material(s) 435 is a dielectric laminate structure. The semiconductor die 404 includes pads 428. In other examples, the pads 428 are part of the metal interconnects 424A, 424B, 424C, and 424D. In such examples, the pads 428 are coupled to (e.g., soldered) to surface pads of the semiconductor die 404.

In the example of FIG. 4, the packaged IC 400 includes a lead frame 430 to which the semiconductor die 404 is attached using die attach 442. Also, the first terminal 411A and the second terminal 411B of the inductor 410 are coupled to different portions of the lead frame 430. The lead frame 430 can be between the inductor 410 and the semiconductor die 404. Each of the metal interconnects 424A, 424B, 424C, and 424D is coupled to a respective pad of the pads 428 and covered by the dielectric laminate structure 408. More specifically, the metal interconnect 424A couples a respective pad of the pads 428 to a first pad 336A and respective external interconnect of the external interconnects 416. The metal interconnect 424B couples a respective pad of the pads 428 to the via 434A. The metal interconnect 424C couples a respective pad of the pads 428 to the via 434B. The metal interconnect 424D couples a respective pad of the pads 428 to a second pad 336B and respective external interconnect of the external interconnects 416.

In some examples, the first dielectric layer 426A of the dielectric laminate structure 408 includes dielectric laminate materials, portions of the vias 434A and 434B, and the pads 428. The second dielectric layer 426B of the dielectric laminate structure 408 includes dielectric laminate materials, portions of the vias 434A and 434B, and vertical portions of the metal interconnects 424A, 424B, 424C, and 424D. The third dielectric layer 426C includes dielectric laminate materials, horizontal vertical portions of the metal interconnects 424A and 424D, vertical portions of the metal interconnects 424B and 424C, and portions of the vias 434A and 434B. The fourth dielectric layer 426D includes dielectric laminate materials, vertical portions of the metal interconnects 424A, 424B, 424C, and 424C, and portions of the vias 434A and 434B. The fifth dielectric layer 426E includes horizontal portions of the metal interconnects 424B and 424C, portions of the vias 434A and 434B, the first pad 436A, and the second pad 436B. In different examples, the dielectric laminate structure 408 may vary with regard to the number of dielectric layers, the number of interconnects, etc. An insulation layer 440 (e.g., a solder resist, a passivation layer, a dielectric layer, etc.) is below the dielectric laminate structure 408 and can cover (and provide electrical insulation to) the first pad 436A and the second pad 436B.

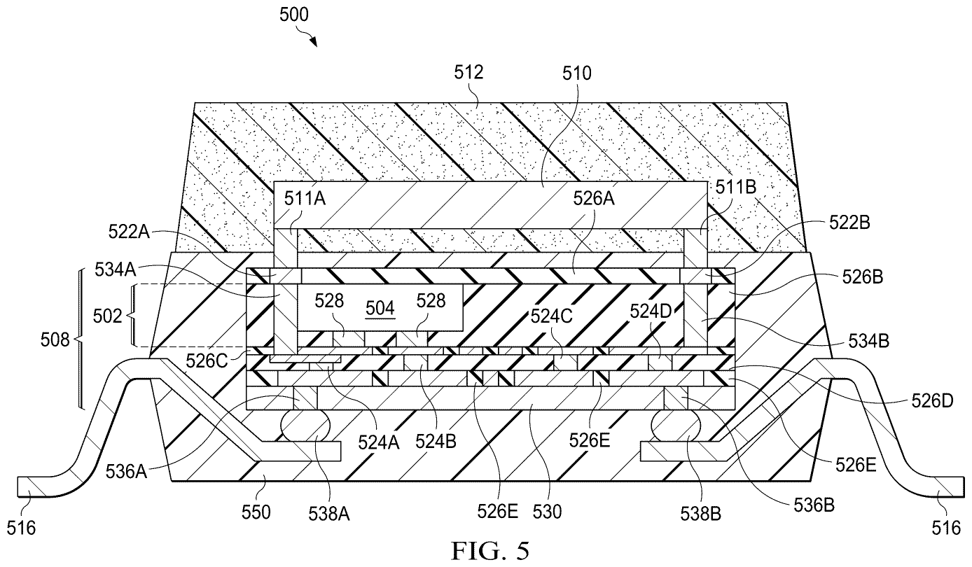

In the example of FIG. 5, the packaged IC 500 includes: an inductor 510 (an example of the inductor 110 in FIG. 1); a magnetic mold compound 512 (an example of the magnetic mold compound 112 in FIG. 1); an embedded die structure 502 including a semiconductor die 504 (an example of the semiconductor die(s) 104 in FIG. 1); a dielectric laminate structure 508 (an example of the dielectric layers 108 in FIG. 1) covering embedded die structure 502; external interconnects 516 (an example of the external interconnects 116 in FIG. 1), and a mold compound 550 (e.g., resin) covering at least parts of external interconnects 516, embedded die structure 502, and dielectric laminate structure 508. In the example of FIG. 5, the semiconductor die 504 is a face-down semiconductor die (with pads facing away from the inductor 510). As shown in FIG. 5, the inductor 510 has a first terminal 511A and a second terminal 511B.

In the example of FIG. 5, the dielectric laminate structure 508 includes a first dielectric layer 526A, a second dielectric layer 526B, a third dielectric layer 526C, a fourth dielectric layer 526D, and a fifth dielectric layer 526E. The dielectric laminate structure 508 covers metal interconnects 524A, 524B, 524C, and 524D, vias 534A and 534B, and lead frame (package substrate) 530. The semiconductor die 504 includes pads 528. In other examples, the pads 528 are part of the metal interconnects 524A and 524B. In such examples, the pads 528 are coupled to (e.g., soldered) to surface pads of the semiconductor die 504.

In the example of FIG. 5, each of the metal interconnects 524A and 524B is coupled to a respective pad of the pads 528. More specifically, the metal interconnect 524A couples a respective pad of the pads 528 to the vias 534A, an exposed pad 522A, and the first terminal 511A of the inductor 510. The metal interconnect 524B couples a respective pad of the pads 528 to the lead frame 530. The metal interconnects 524C and 524D may couple to circuitry below the semiconductor die 504. In some examples, the second terminal 511B of the inductor 510 couples to such circuitry or a respective external terminal 516 via the exposed pad 522B, the via 534B, the metal interconnect 524D and/or other metal interconnects. The mold compound 550 encloses the dielectric laminate structure 508. The external interconnects 516 couple to respective solder joints (e.g., solder 538A and 538B) and extend through the mold compound 550, providing respective conductive contacts external to the packaged IC 500.

In some examples, the first dielectric layer 526A of the dielectric laminate structure 508 includes a dielectric material covering exposed pads 522A and 522B. The second dielectric layer 526B of the dielectric laminate structure 508 includes dielectric material covering portions of the vias 534A and 534B, the semiconductor die 504, and the pads 528. The third dielectric layer 526C includes dielectric material covering portions of the metal interconnects 524A and 524B. The fourth dielectric layer 526D includes dielectric material covering vertical portions of the metal interconnects 524A, 524B, 524C, and 524D. The fifth dielectric layer 526E includes dielectric material covering the lead frame 530 and interconnects 536A and 536B through the lead frame 530. In the example of FIG. 5, the interconnect 536A is coupled to a respective interconnect of the external interconnects 516 using solder 538A, and the interconnect 536B is coupled to a respective interconnect of the external interconnects 516 using solder 538B. In different examples, the dielectric laminate structure 508 may vary with regard to the number of dielectric layers, the number of interconnects, etc.

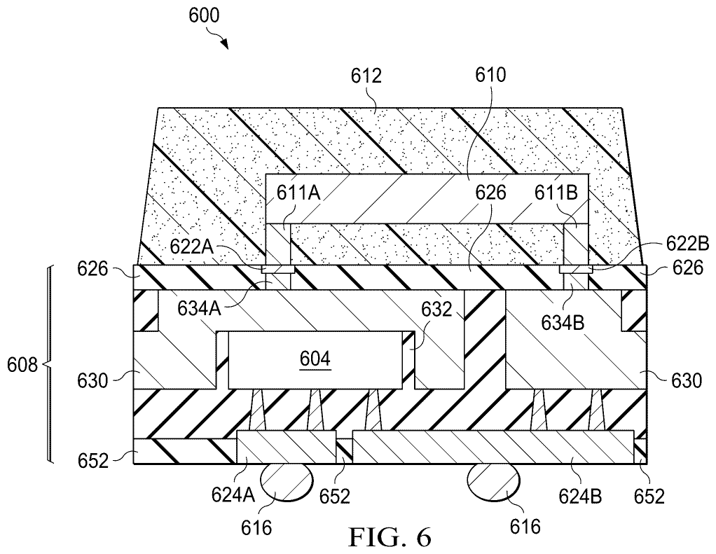

In the example of FIG. 6, the packaged IC 600 includes: an inductor 610 (an example of the inductor 110 in FIG. 1); a magnetic mold compound 612 (an example of the magnetic mold compound 112 in FIG. 1); a semiconductor die 604 (an example of the semiconductor die(s) 104 in FIG. 1); a dielectric laminate structure 608 (an example of the dielectric layers 108 in FIG. 1) covering the semiconductor die 604; and external interconnects 616 (an example of the external interconnects 116 in FIG. 1). In the example of FIG. 6, the semiconductor die 604 is a face-down semiconductor die (with pads facing away from the inductor 610). As shown in FIG. 6, the inductor 610 has a first terminal 611A and a second terminal 611B.

In the example of FIG. 6, the dielectric laminate structure 608 covers a lead frame (package substrate) 630 and the semiconductor die 604. Lead frame 630 includes a recess 632 in which the semiconductor die 604 is positioned. The dielectric laminate structure 608 includes dielectric layers 626 and 652 and covers metal interconnects 624A and 624B, which can include pillars, columns, and/or can be part of a redistribution layer. In the example of FIG. 6, the metal interconnect 624A is coupled between respective pads (not shown) of the semiconductor die 604 and an external interconnect of the external interconnects 616. The metal interconnect 624B is coupled between a respective pad (not shown) of the semiconductor die 604, a second portion of the lead frame 630, and another external interconnect of the external interconnects 616. Dielectric layer 652 (e.g., a solder mask) covers (and provides electrical insulation to) metal interconnects 624A and 624B.

In the example of FIG. 6, the first terminal 611A of the inductor 610 is coupled to an exposed pad 622A. The second terminal 611B of the inductor 610 is coupled to an exposed pad 622B. The exposed pad 622A is coupled to the first portion of the lead frame 630 by a via 634A. The exposed pad 622B is coupled to the second portion of the lead frame 630 by a via 634B. In the example of FIG. 6, the semiconductor die 604 is in a cavity of the first portion of the lead frame 630, which can reduce the overall dimensions of the packaged IC 600.

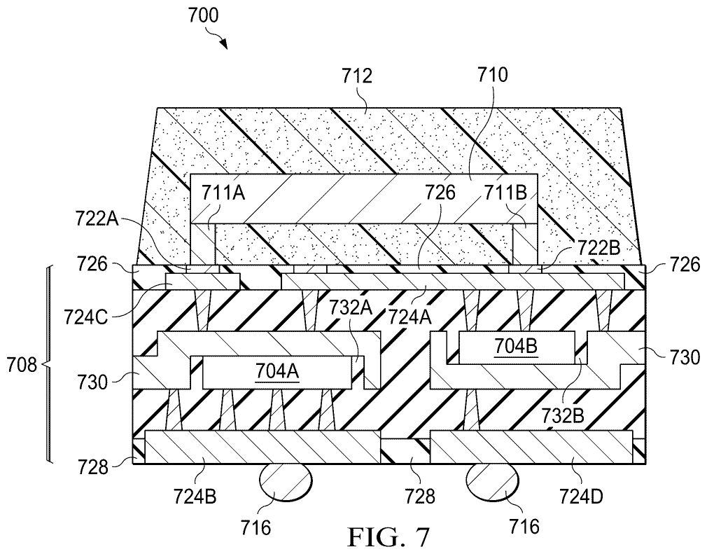

In the example of FIG. 7, the packaged IC 700 includes: an inductor 710 (an example of the inductor 110 in FIG. 1); a magnetic mold compound 712 (an example of the magnetic mold compound 112 in FIG. 1); a first semiconductor die 704A (an example of the semiconductor die(s) 104 in FIG. 1); a second semiconductor die 704B (an example of the semiconductor die(s) 104 in FIG. 1); a dielectric laminate structure 708 (an example of the dielectric layers 108 in FIG. 1) covering the first semiconductor die 704A and the second semiconductor die 704B; and external interconnects 716 (an example of the external interconnects 116 in FIG. 1). In the example of FIG. 7, the first semiconductor die 704A is a face-down semiconductor die (with pads facing away from the inductor 710), while the second semiconductor die 704B is a face-up semiconductor die (with pads facing the inductor 710). As shown in FIG. 7, the inductor 710 has a first terminal 711A and a second terminal 711B. The first terminal 711A of the inductor 710 is coupled to an exposed pad 722A. The second terminal 711B of the inductor 710 is coupled to an exposed pad 722B.

In the example of FIG. 7, the dielectric laminate structure 708 includes dielectric layers 726 and 728 and covering a lead frame (package substrate) 730, and the first and second semiconductor dies 704A and 704B. The dielectric laminate structure 708 includes multiple dielectric layers forming a laminate structure and covering interconnects 724A, 724B, 724C, and 724D. In the example of FIG. 7, the interconnect 724A is coupled between respective pads (not shown) of the second semiconductor die 704B, a first portion of the lead frame 730, a second portion of the lead frame 730, and the exposed pad 722B. The interconnects 724C are coupled between respective pads (not shown) of the first semiconductor die 704A, the first portion of the lead frame 730, the second portion of the lead frame 730, and first and second terminals 711A and 711B, and are covered by dielectric layer 726. Interconnects 724B and 724D provide electrical connection to external interconnects 716 and can be covered by dielectric layer 728 (e.g., a solder resist). In the example of FIG. 7, the first semiconductor die 704A is in a recess 732A of the first portion of the lead frame 730, and the second semiconductor die 704B is in a recess 732B of the second portion of the lead frame 730, which can reduce overall dimensions of the packaged IC 700.

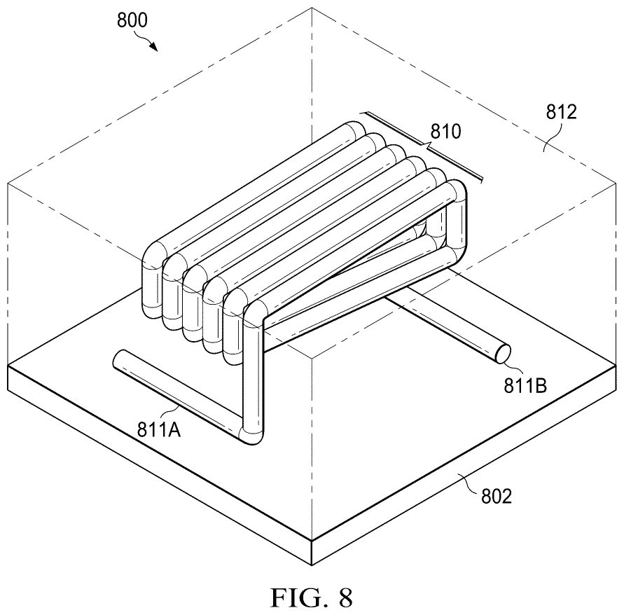

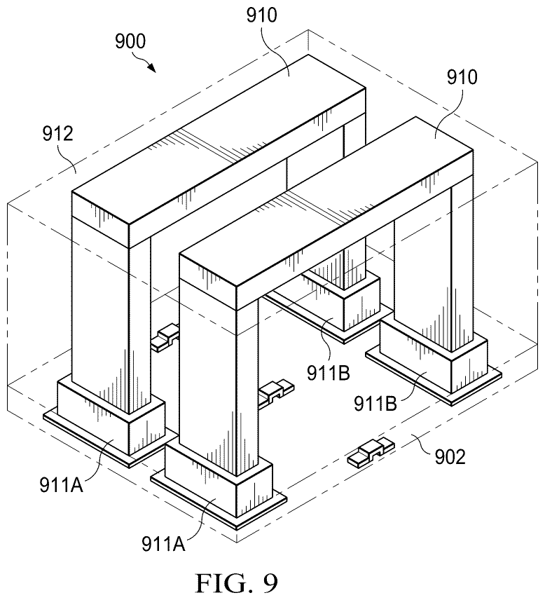

FIGS. 8 and 9 are perspective views 800 and 900 of external inductors in magnetic mold compound. In the perspective view 800 of FIG. 8, an inductor 810 (an example of the inductor 110 in FIG. 1) in a magnetic mold compound 812 (an example of the magnetic mold compound 112 in FIG. 1) is represented over an upper surface of encapsulation material(s) 802 (an example of the encapsulation material(s) 102 in FIG. 1). In the example of FIG. 8, the inductor 810 has a first terminal 811A, a second terminal 811B, and a coil between the first terminal 811A and the second terminal 811B. The coil of the inductor 810 has a rectangular shape and the coil orientation is parallel to the upper surface of the encapsulation material(s) 802.

In the perspective view 900 of FIG. 9, an external inductor 910 (an example of the inductor 110 in FIG. 1) in a magnetic mold compound 912 (an example of the magnetic mold compound 112 in FIG. 1) is represented over an upper surface of encapsulation material(s) 002 (an example of the encapsulation material(s) 102 in FIG. 1). In the example of FIG. 9, the inductor 910 has first terminals 911A, second terminals 911B, and partial coils between the first terminals 911A and the second terminals 911B. The partial coils of the inductor 810 have a rectangular shape and the partial coil orientation is parallel to the upper surface of the encapsulation material(s) 902.

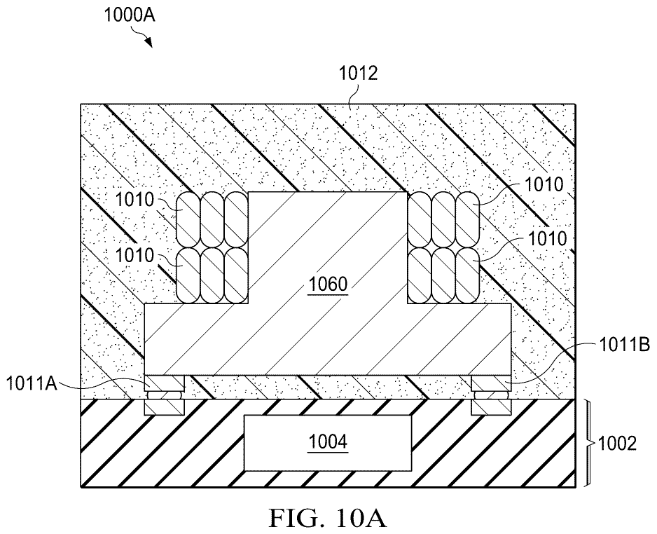

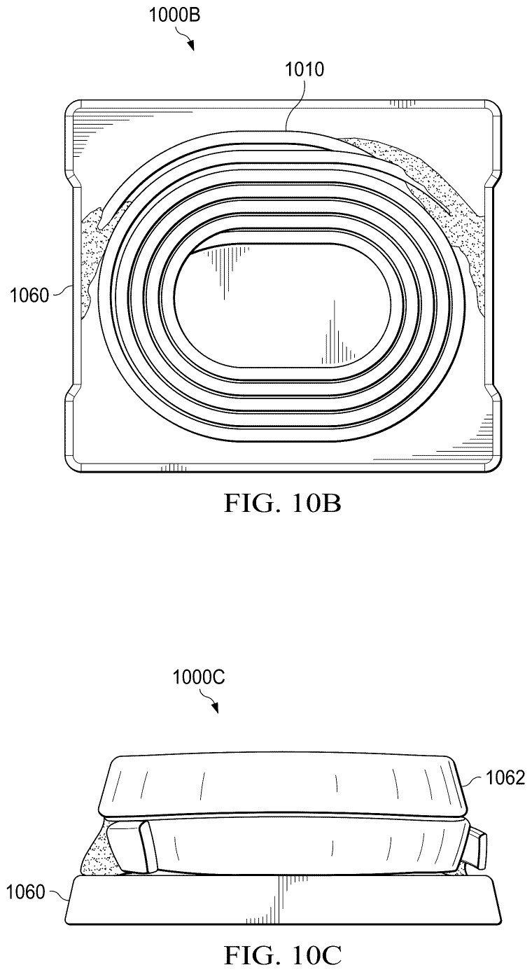

FIGS. 10A to 10C are different views 1000A, 1000B, and 1000C of a T-shaped core 1060 for an inductor 1010. In the cross-sectional view 1000A of FIG. 10A, the T-shaped core 1060 has an upside down T shape with an upper portion and a lower portion (base). In FIG. 10A, the inductor 1010 (an example of the inductor 110 in FIG. 1) is in magnetic mold compound 1012 (an example of the magnetic mold compound 112 in FIG. 1 over an embedded die structure 1002 including the semiconductor die 1004 and internal metal interconnects, with at least the metal interconnects surrounded by a dielectric laminate structure such as examples of dielectric laminate structure described herein. The embedded die structure 1002 includes a semiconductor die 1004 (an example of the semiconductor die(s) 104 in FIG. 1) covered by the dielectric laminate structure. In the example of FIG. 10A, the coil of the inductor 1010 is oriented orthogonal of the surface of the embedded die structure 1002 and wraps around the upper portion of the T-shaped core 1060. In the example of FIG. 10, the inductor 1010 includes a first terminal 1011A and a second terminal 1011B, which may couple to the semiconductor die 1004 via exposed pads and interconnects of the embedded die structure 1002 as described herein. With the T-shaped core 1060, the overall inductance of the inductor 1010 is improved compared to an inductor without a core.

In the top view 1000B of FIG. 10B, the coil of the inductor 1010 is represented as having a circular shape and is wrapped around the upper portion of the T-shaped core 1060. In the side view 1000C of FIG. 10C, the T-shaped core 1060 is represented. In the example of FIG. 10C, the upper portion of the T-shaped core 1060 is covered by a metallic material 1062, while the base of the T-shaped core 1060 is uncovered.

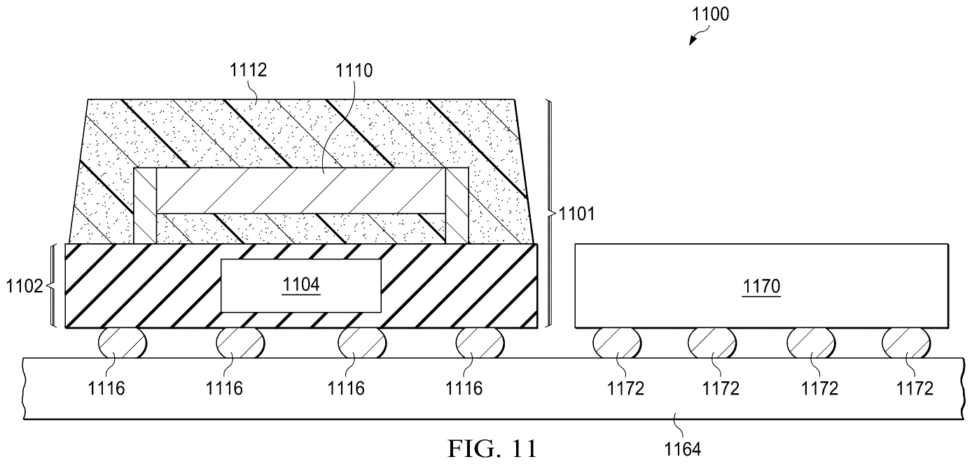

FIG. 11 is a cross-sectional view of a system 1100. The system 1100 includes a packaged IC 1101, a circuit board 1164, and a processor 1170. The processor includes external interconnects 1172. The packaged IC 1101 is an example of the packaged IC 100 in FIG. 1, the packaged IC 200 in FIG. 2, the packaged IC 300 in FIG. 3, the packaged IC 400 in FIG. 4, the packaged IC 500 in FIG. 5, the packaged IC 600 in FIG. 6, or the packaged IC 700 in FIG. 7. In the example of FIG. 11, the packaged IC 1101 includes: an inductor 1110 in a magnetic mold compound 1112 over an embedded die structure 1102; and external interconnects 1116. The embedded die structure 1102 includes a semiconductor die 1104 (an example of the semiconductor die(s) 104 in FIG. 1) and internal interconnects, with at least the internal interconnects enclosed in a dielectric laminate structure, including examples of the dielectric laminate structure as described herein.

In the example of FIG. 11, the packaged IC 1101 is coupled to the processor 1170 via the external interconnects 1116, the circuit board 1164, and the external interconnects 1172. In some examples, the packaged IC 1101 is a power converter and is used to power the processor 1170.

In some examples, a system (e.g., the system 1100) includes: a circuit board (e.g., the circuit board 1164); a processor (e.g., the processor 1170) mounted on the circuit board; and a power module (e.g., the packaged IC 1101) mounted on the circuit board. The power module includes: a semiconductor die (e.g., the semiconductor die 1104); an inductor (e.g., the inductor 1110) on the semiconductor die; a dielectric laminate structure (e.g., part of the embedded die structure 1102) including multiple dielectric layers; a metal interconnect structure (part of the embedded die structure 1102) in the dielectric laminate structure and coupled between the inductor and the semiconductor die; and a magnetic mold compound (e.g., the magnetic mold compound 1112) covering the inductor. The magnetic mold compound has at least a same footprint as the power module. In some examples, the power module includes a power converter configured to provide power to the processor via the circuit board. In some examples, the semiconductor die (e.g., the semiconductor die 1104) is in the dielectric laminate structure. With a packaged IC or power module as described herein, module ripple current is reduced and module efficiency is increased.

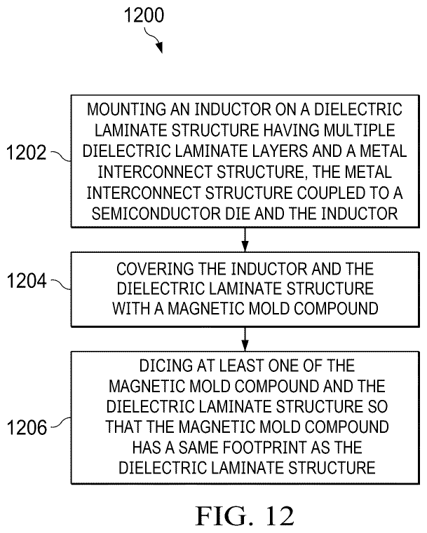

FIG. 12 is a flowchart illustrating a method 1200 for fabricating a packaged IC (e.g., the packaged IC 100 in FIG. 1, the packaged IC 200 in FIG. 2, the packaged IC 300 in FIG. 3, the packaged IC 400 in FIG. 4, the packaged IC 500 in FIG. 5, the packaged IC 600 in FIG. 6, or the packaged IC 700 in FIG. 7). In the example of FIG. 12, the method 1200 includes mounting an inductor (e.g., the inductor 110 in FIG. 1 or the other inductors herein) on a dielectric laminate structure having multiple laminate dielectric layers and a metal interconnector structure (the interconnects of the dielectric layers 108 in FIG. 1 or related interconnects herein) at operation 1202. The metal interconnect structure formed in operation 1202 is coupled to a semiconductor die and the inductor. At operation 1204, the inductor and the dielectric laminate structure are covered with a magnetic mold compound (e.g., the magnetic mold compound 112 in FIG. 1, or related magnetic mold compounds herein). At operation 1206, at least one of the magnetic mold compound and the dielectric laminate structure is diced so that the magnetic mold compound has a same footprint as the dielectric laminate structure. In some examples, the semiconductor die is in the dielectric laminate structure.

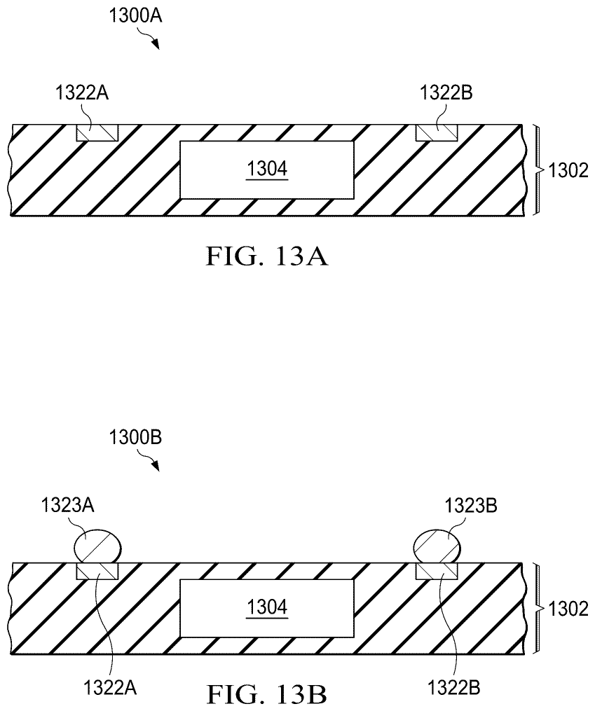

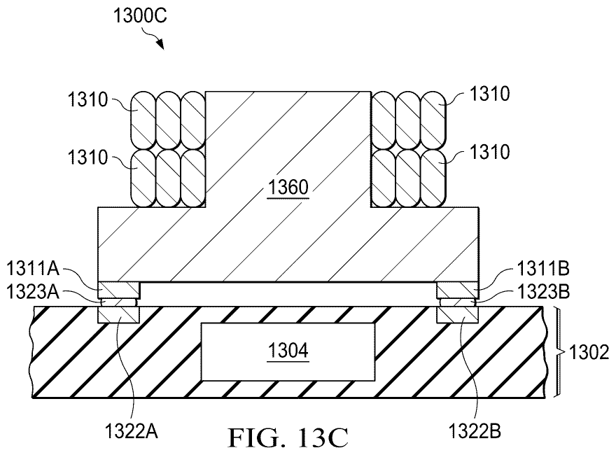

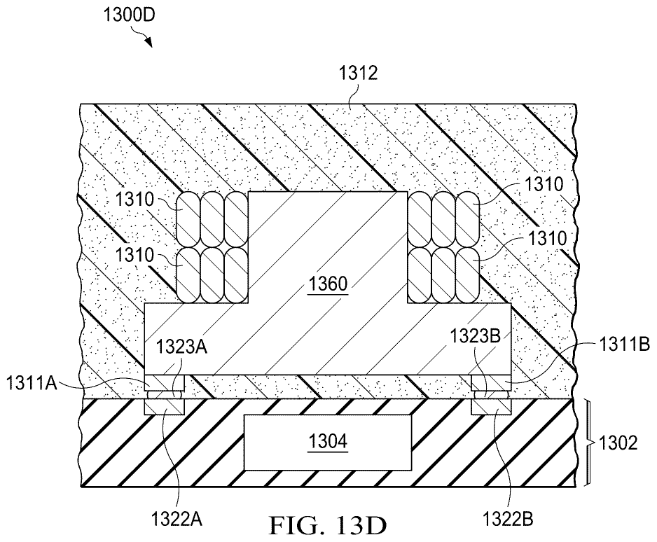

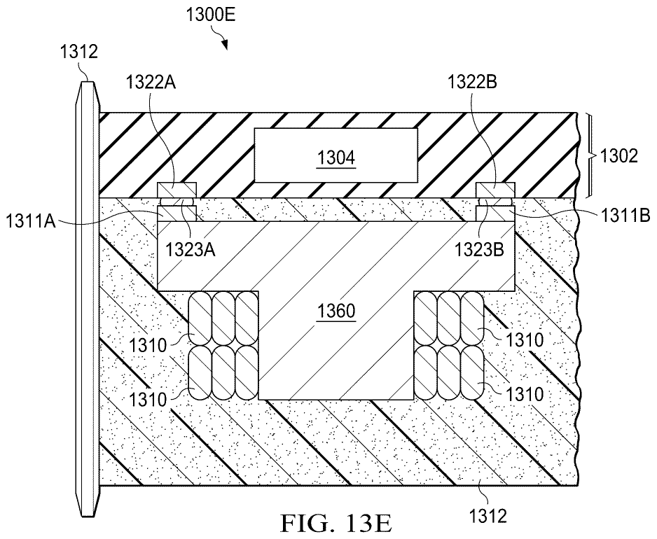

FIGS. 13A to 13E are cross-sectional views 1300A, 1300B, 1300C, 1300D, and 1300E of a device during the operations of method 1200. The cross-sectional view 1300A shows that encapsulation material(s) (e.g., the encapsulation material(s) 102 in FIG. 1, or related encapsulation material(s) herein) with an embedded semiconductor die 1304 (an example of the semiconductor die(s) 104 in FIG. 1, or related semiconductor dies herein) and exposed pads 1322A and 1322B (examples of the first and second exposed pads 222A and 222B in FIG. 2, the first and second exposed pads 322A and 322B in FIG. 3, the exposed pads 622A and 622B in FIG. 6, or the exposed pads 722A and 722B in FIG. 7).

The cross-sectional view 1300B shows that solder 1323A is formed on the exposed pad 1322A and solder 1323B is formed on the exposed pad 1322B.

The cross-sectional view 1300C shows that an inductor 1310 (e.g., the inductor 110 in FIG. 1, or related inductor herein) and a core 1360 (e.g., the T-shaped core 1060 in FIG. 10A to 10C, or another core) are mounted on a surface of encapsulation material(s) 1302. In the example of FIG. 13C, the inductor 1310 has a first terminal 1311A and a second terminal 1311B. The first terminal 1311A of the inductor 1310 is aligned with the exposed pad 1322A and the solder 1323A. The second terminal 1311B of in the inductor 1310 is aligned with the exposed pad 1322B and the solder 1323B. The core 1360 can be positioned using, for example, pick-and-place (PnP), and the solder 1323A and 1323B can be formed in a reflow process. The cross-sectional views 1300A-1300C can be part of operation 1202.

The cross-sectional view 1300D shows that a magnetic mold compound 1312 is formed over and covering the inductor 1310 and the core 1360. The cross-sectional view 1300D can represent operation 1204.

View 1300E illustrates a dicing operation, where individual packaged ICs are diced, so that the magnetic mold compound 1312 has at least a same footprint as the dielectric laminate structure of the encapsulation material(s) 1302. View 1300E can represent operation 1206.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Modifications are possible in the described embodiments, and other embodiments are possible, within the scope of the claims.

What is claimed is:

1. A packaged integrated circuit (IC) comprising:
a semiconductor die;
an inductor on the semiconductor die;
a dielectric laminate structure including multiple dielectric layers;
a metal interconnect structure in the dielectric laminate structure and coupled between the inductor and the semiconductor die; and
a magnetic mold compound covering the inductor, the magnetic mold compound having at least a same footprint as the dielectric laminate structure.

2. The packaged IC of claim 1, wherein at least part of the dielectric laminate structure is between the inductor and the semiconductor die.

3. The packaged IC of claim 1, wherein the semiconductor die is between the inductor and at least part of the dielectric laminate structure.

4. The packaged IC of claim 1, further comprising:
a package substrate on which the semiconductor die is mounted; and
external metal interconnects coupled to the package substrate.

5. The packaged IC of claim 4, wherein the external metal interconnects include at least one of: metal pads, solder balls, or leads.

6. The packaged IC of claim 4, wherein the package substrate and the external metal interconnects are part of a BGA package, an LGA package, or a QFN package.

7. The packaged IC of claim 4, wherein the package substrate is between the inductor and the semiconductor die.

8. The packaged IC of claim 7, wherein the package substrate includes a recess, and the semiconductor die is in the recess.

9. The packaged IC of claim 1, wherein the semiconductor die is a first semiconductor die, and the packaged IC further comprises a second semiconductor die coupled to the metal interconnect structure.

10. The packaged IC of claim 1, wherein the dielectric laminate structure is a first dielectric laminate structure, the metal interconnect structure is a first metal interconnect structure, the packaged IC further comprises a second dielectric laminate structure and a second metal interconnect structure in the second dielectric laminate structure, and the semiconductor die between the first and second dielectric laminate structures.

11. The packaged IC of claim 1, wherein the inductor includes a coil, the packaged IC further comprises a core that includes at least a portion that extends though the coil, and the magnetic mold compound covers the inductor and the core.

12. The packaged IC of claim 11, wherein the portion is a first portion, and the core includes a second portion between the coil and the semiconductor die.

13. The packaged IC of claim 12, wherein the first and second portions form a T-shape.

14. The packaged IC of claim 1, further comprising a passive component covered by the magnetic mold compound and coupled to the semiconductor die via the metal interconnect structure.

15. The packaged IC of claim 10, wherein at least one of first dielectric laminate structure and the second dielectric laminate structure include build-up films.

16. The packaged IC of claim 11, wherein at least some of the multiple dielectric layers include at least one of: epoxy; benzoxazine; polyimide; or bismaleimide-triazine.

17. The packaged IC of claim 11, wherein the semiconductor die and the inductor are part of a power converter.

18. A system comprising:
a circuit board;
a processor mounted on the circuit board; and
a power module mounted on the circuit board, the power module including:
a semiconductor die;
an inductor on the semiconductor die;
a dielectric laminate structure including multiple dielectric layers;
a metal interconnect structure in the dielectric laminate structure and coupled between the inductor and the semiconductor die; and
a magnetic mold compound covering the inductor, the magnetic mold compound having at least a same footprint as the power module.

19. The system of claim 18, wherein the power module includes a power converter configured to provide power to the processor via the circuit board.

20. The system of claim 18, wherein the semiconductor die is in the dielectric laminate structure.

21. A method comprising:
mounting an inductor on a dielectric laminate structure having multiple dielectric layers and a metal interconnect structure, the metal interconnect structure coupled to a semiconductor die and the inductor;
covering the inductor coupled to the dielectric laminate structure with a magnetic mold compound; and
dicing at least one of the magnetic mold compound or the dielectric laminate structure so that the magnetic mold compound has a same footprint as the dielectric laminate structure.

22. The method of claim 21, wherein the semiconductor die is in the dielectric laminate structure.
